(19) United States
(12) Patent Application Publication
(10) Pub. No.: US 2014/0375194 A1
(43) Pub. Date: Dec. 25, 2014

(54) INFORMATION TERMINAL APPARATUS

(71) Applicant: SONY CORPORATION, Tokyo (JP)

(72) Inventors: Kiyokuni Arima, Nagano (JP); Yujin Morisawa, Tokyo (JP)

(21) Appl. No.: 14/370,375

(22) PCT Filed: Dec. 11, 2012
(86) PCT No.: PCT/JP2012/007894

§ 371 Date: Jul. 2, 2014

(30) Foreign Application Priority Data
Feb. 3, 2012 (JP) 2012-022530

(51) Int. Cl. G06F 1/16; H05K 5/02

(52) U.S. Cl. CPC G06F 1/1601; G06F 1/1637; H05K 5/0226
USPC 312/322

(57) ABSTRACT

[Object] To provide an information terminal apparatus having an improved structure for connecting a first body and a second body.

[Solving Means] An information terminal apparatus according to the present disclosure includes a first body, a second body, a rotating shaft, and a parallel linking mechanism. The rotating shaft is connected to the first body. The parallel linking mechanism is able to rotate in an integrated manner with the rotating shaft. The parallel linking mechanism has a first arm rotatably connected to the second body, a second arm rotatably connected to the second body, and a linking arm to link the first arm to the second arm in a parallel manner.

### TECHNICAL FIELD

The present disclosure relates to information terminal apparatuses such as notebook PCs (Personal Computers).

### BACKGROUND ART

A mobile device described in Patent Document 1 is provided with a first casing (10) having an operation key, a second casing (20) having a display panel, and coupling members (30) and (40) to connect them. The coupling member (30) (same for (40)) is rotatably connected to the first casing (10) and the second casing (20) by the corresponding ones of hinge units (50) and (60) (for example, see paragraphs [0013] to [0015] and FIGS. 2 and 3 of Patent Document 1).
Patent Document 1: Japanese Patent Application Laid-open No. 2010-65840

### DISCLOSURE OF THE INVENTION

### Problem to be Solved by the Invention

In recent years, with diversification of the uses of information terminal apparatuses such as the above-mentioned mobile devices, there is a demand for the necessity of improvement of creation in mechanical structures of the information terminal apparatuses.

An object of the present disclosure is to provide an information terminal apparatus having an improved structure for connecting a first body and a second body.

### Means for Solving the Problem

In order to solve the problems described above, according to an information terminal apparatus of the present disclosure, the information terminal apparatus includes a first body, a second body, a rotating shaft, and a parallel linking member. The rotating shaft is connected to the first body. The parallel linking member is capable of rotating in an integrated manner with the rotating shaft. The parallel linking member has a first arm rotatably connected to the second body, a second arm rotatably connected to the second body, and a linking arm to link the first arm to the second arm in a parallel manner.

This allows the first body and the second body to move in accordance with a movement of the parallel linking member connected therebetween.

The information terminal apparatus may further include a display portion having a display surface being provided in parallel to the linking arm, the display portion being provided on the second body. This allows a user to change an angle of the second body with respect to the first body, which is an angle of the display surface of the display portion, according to an angle of the linking arm of the parallel linking member.

The parallel linking member may have a slide shaft which is connected, rotatably and slidably with respect to the first body, to a part where the second arm and the linking arm are connected. This allows the parallel linking member to operate the slide shaft while causing the slide shaft to slide against the first body.

The first body may have a guide portion including a first slide end and a second slide end opposite to the first slide end, which guide portion guides sliding of the slide shaft.

The slide shaft may coincide with the rotating shaft in a state where the slide shaft is positioned at the first slide end of the guide portion.

This allows the second body to rotate integrally with the first arm, the second arm and the linking arm of the parallel linking member, around the rotating shaft, in a state where the first arm, the second arm and the linking arm are in parallel, and the second body may be in a stable posture while rotating, in the following ways.

The second body may be rotatable integrally with the first arm, the second arm and the linking arm, around the rotating shaft, in a state where the slide shaft is coincident with the rotating shaft.

The display portion may be provided on the second body. The second body may have a display surface provided in parallel to the linking arm, the display surface being provided on the display portion. The second body may have an opposite surface provided on a side opposite to the display surface. The first body and the second body may overlap in such a manner that the first arm, the second arm and the linking arm are in parallel, and the opposite surface of the second body faces the first body, in a state where the slide shaft is positioned at the second slide end of the guide portion.

The parallel linking member may be provided in a mechanism having a pair of parallel linking members disposed in both sides of the first body. This allows the first and second bodies to be moved relative to each other in a stable posture.

The information terminal apparatus may further include a coupling member to couple first arms of the pair of parallel linking members integrally to each other. This enhances the rigidity of each of the both first arms that rotates integrally with the rotating shaft. As a result, the relative movement of the first and second bodies can be more stable.

The coupling member may have the rotating shaft. This may make it unnecessary to provide a separate rotating shaft if the coupling member is provided; and allow downsizing of the information terminal apparatus.

### EFFECTS OF THE INVENTION

As described above, according to the present disclosure, it makes it possible to realize an information terminal apparatus having an improved structure for connecting a first body and a second body.

### BRIEF DESCRIPTION OF DRAWINGS

FIG. 1 is a perspective view showing a notebook PC as an information terminal apparatus (an electronic computer) according to an embodiment of the present disclosure.

FIG. 2 is a perspective view showing the PC in a state where a display body is closed with respect to a main body.

FIG. 3 is a perspective view showing the PC in a state where a display portion of the display body is facing outward.

FIG. 4 is a side view showing the PC in a shut state shown in FIG. 2.

FIG. 5 is a side view showing the PC in a tablet state shown in FIG. 3.

FIG. 6 is a side view showing the PC in a state where the display body is kept in an inclined posture with respect to a horizontal plane (or a vertical axis) by the operation of a parallel linking mechanism.

FIG. 7 is a perspective view showing the PC as seen from the rear side for mainly illustrating the parallel linking mechanism.

FIG. 8 is a perspective view showing a part near shoulder portions of first and second arms of the parallel linking mechanism as seen from its inner side.

FIG. 9 is a figure showing a clamshell opening and closing action.

FIG. 10 is a figure showing a part near a slide shaft as seen from X-axis direction, in a state where the PC is operable to make a clamshell opening and closing action.

FIGS. 11A to 11C are figures showing a tablet opening and closing action.

FIGS. 12A to 12C are figures showing the actions of the parallel linking mechanism each corresponding to the action timings of FIGS. 11A to 11C.

FIG. 13 is a perspective view showing the PC being in the state shown in FIG. 11A.

FIG. 14A is a perspective view showing an information terminal apparatus (an electronic computer) according to another embodiment as seen from an upper right position of the rear side. FIG. 14B is a perspective view showing a state where a display body (display portion) thereof is opened, as seen from an upper right position of the front side. FIG. 14C is a perspective view thereof as seen from a bottom left position of the rear side.

FIGS. 15A and 15B respectively are a plan view and a bottom view of the computer shown in FIG. 14 in a closed state (a shut state).

FIGS. 16A, 16B and 16C respectively are a front view, a back view and a left-side view of the computer shown in FIG. 14. A right-side view is omitted as it is bilaterally symmetric with respect to the left-side view.

FIGS. 17A and 17B respectively are a perspective view as seen from an upper right position of the front side, and a perspective view as seen from an upper right position of the rear side, of the computer shown in FIG. 14 in a state where the display body thereof is opened (in a state where its posture is different by angle from that shown in FIG. 14B).

FIGS. 18A and 18B are a plan view and a bottom view of the computer in a state where the posture of the display body is that as shown in FIG. 17.

FIGS. 19A, 19B and 19C are a front view, a back view and a left-side view of the computer in a state where the posture of the display body is that as shown in FIG. 17. A right-side view is omitted as it is bilaterally symmetric with respect to the left-side view.

FIGS. 20A and 20B respectively are a perspective view as seen from an upper right position of the front side, and a perspective view as seen from an upper right position of the rear side, of the computer shown in FIG. 14 in which the display body is in a different state (a viewer state).

FIGS. 21A and 21B are a plan view and a bottom view of the computer in a state where the posture of the display body is that as shown in FIG. 20.

FIGS. 22A, 22B and 22C are a front view, a back view and a left-side view of the computer in a state where the posture of the display body is that as shown in FIG. 17. A right-side view is omitted as it is bilaterally symmetric with respect to the left-side view.

FIG. 23 is a perspective view as seen from an upper right position of the front side of the computer shown in FIG. 14 in which the display body is in another different state (a tablet state).

### MODE(S) FOR CARRYING OUT THE INVENTION

Hereinafter, some embodiments of the present disclosure will be described.

[Configuration of Information Terminal Apparatus]

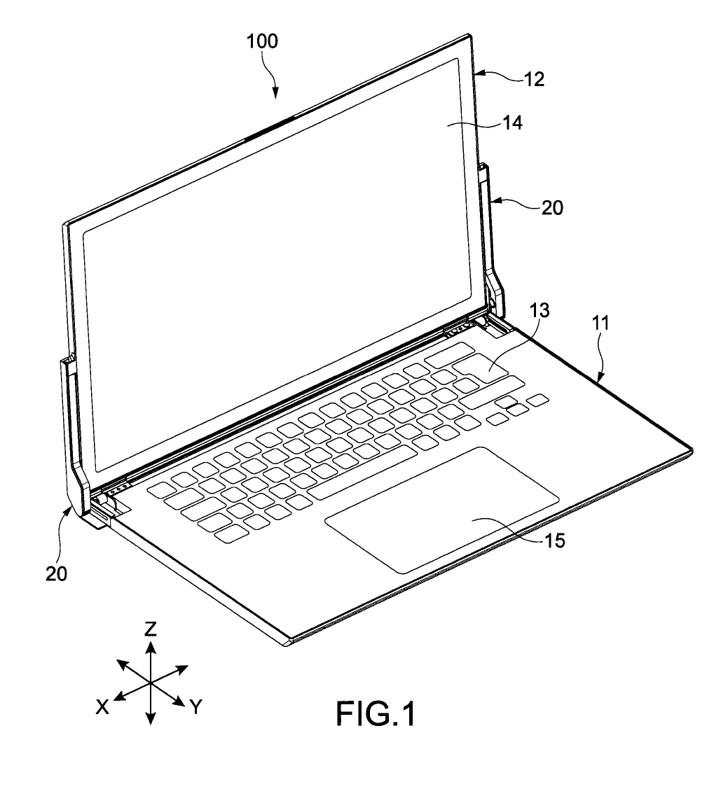

FIG. 1 is a perspective view showing a notebook (clamshell) PC as an information terminal apparatus (an electronic computer) according to an embodiment of the present disclosure.

A PC 100 is provided with a main body (first body) 11, a display body (second body), 12 and parallel linking mechanisms (parallel linking members) 20 which connect the main body 11 and the display body 12 to each other. Each of the main body 11 and the display body 12 has a roughly flat plate-like and rectangular shape. The parallel linking mechanisms 20 are provided in a pair disposed in both of the right and left sides of the PC 100.

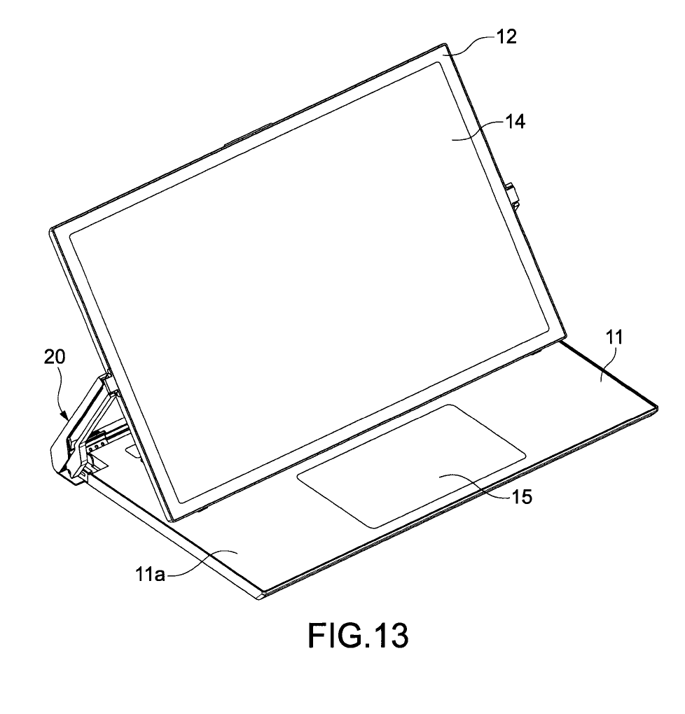

Typically, the main body 11 has a keyboard 13, a touch pad 15, and the like, as an operation input part. Inside a casing of the main body 11, although not shown, there are provided a main circuit board and the like, in which, the main circuit board has a circuit chip of CPU (Central Processing Unit) and the like being mounted thereon. To a display portion 14 of the display body 12, for example, touch panel type may be employed. Illustration by drawing of the keyboard 13 and the touch pad 15 is omitted in the figures other than FIGS. 1 and 13 in FIGS. 1 to 13.

A communication between the main body 11 and the display body 12 may be performed via a cable or a flexible circuit board which is not shown. In this case, the cables may be disposed inside a cover which covers the linking mechanism, which cover is not shown. Alternatively, the main body 11 and the display body 12 may communicate with each other by using a known wireless communication technology such as, for example, Near Field Communication.

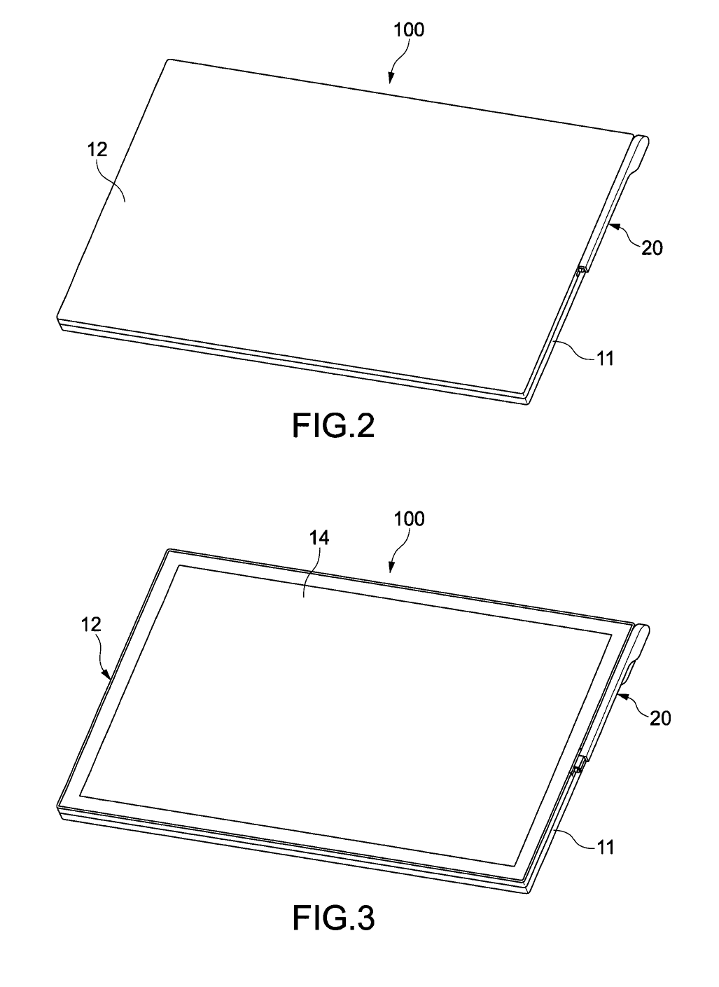

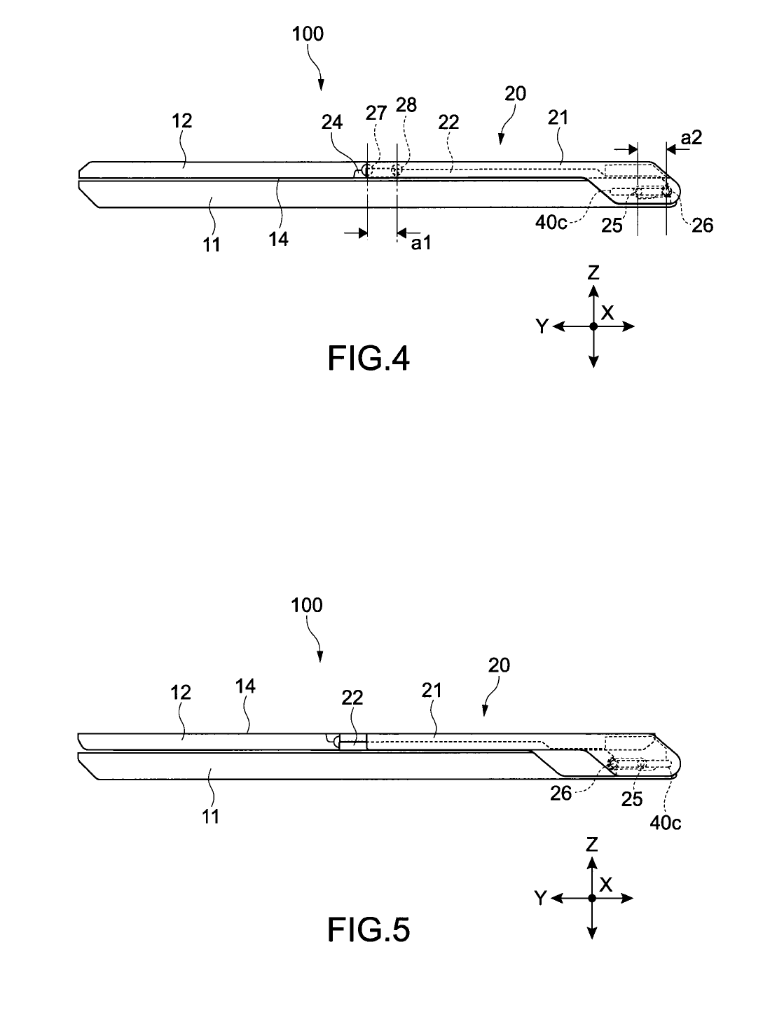

FIG. 2 is a perspective view showing the PC 100 in a state where the display body 12 is closed with respect to the main body 11. Hereinafter, this state of the PC as shown in FIG. 2 will be referred to as a “shut state”. FIG. 3 is a perspective view showing the PC 100 in a state where the display portion 14 of the display body 12 is facing outward. Hereinafter, this state of the PC as shown in FIG. 3 will be referred to as a “tablet state”. FIG. 4 is a side view showing the PC 100 in the shut state shown in FIG. 2. FIG. 5 is a side view showing the PC 100 in the tablet state shown in FIG. 3.

In such a manner, this PC 100 is operable to switch the shut state and the tablet state by rotating the display body 12 substantially 180 degrees with respect to the main body 11.

In the following description, for convenience of explanation, a plane in which the main body 11 is placed will be referred to as a “horizontal plane (X-Y plane)”; and an axis which is perpendicular to the horizontal plane will be referred to as a “vertical axis (Z-axis)”. A side of the PC 100 provided with the touch pad 15 in the Y-axis direction of the main body 11 will be referred to as “front (front side)”; and the side with the keyboard 13 will be referred to as “back (rear side)”. In addition, in the following description, unless it is necessary to explain both of the parallel linking mechanisms 20, only one of the parallel linking mechanisms 20 will be explained.

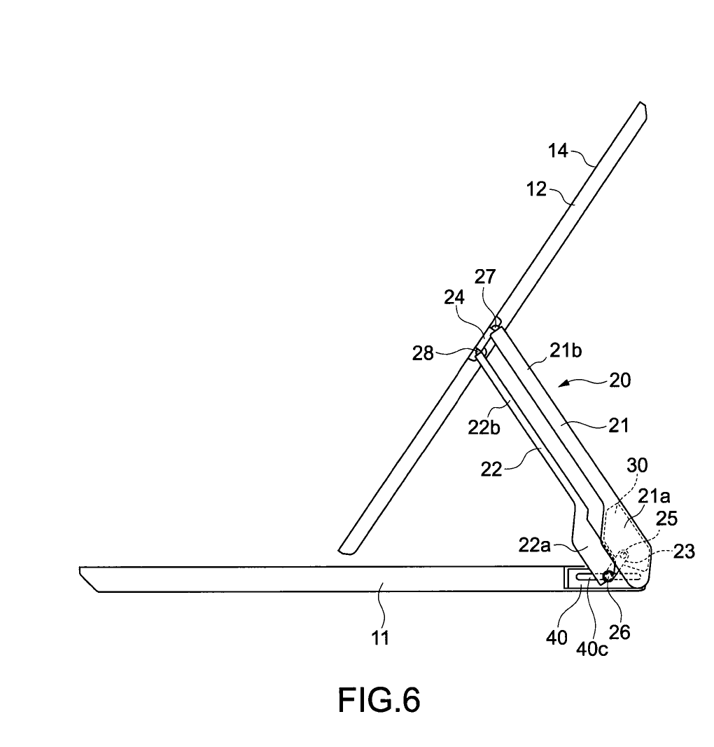

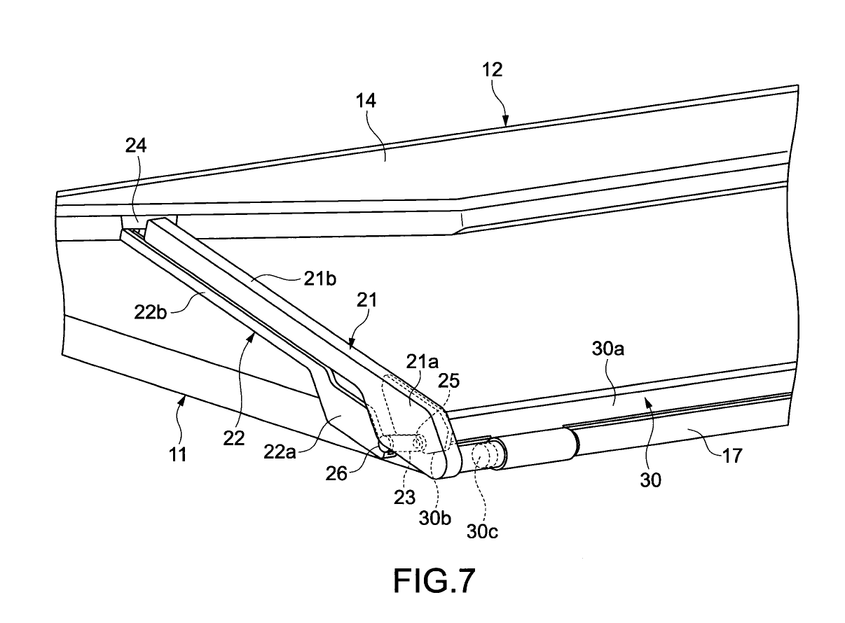

FIG. 6 is a side view showing the PC 100 in a state where the display body 12 is kept in an inclined posture with respect to the horizontal plane (or the vertical axis) by the operation of the parallel linking mechanism 20. FIG. 7 is a perspective view showing the PC 100 as seen from the rear side for mainly illustrating the parallel linking mechanism 20.

As shown in FIG. 7, a shaft attachment portion 17 is formed in a back end portion of the main body 11. To the shaft attachment portion 17, a rotating base frame 30 is rotatably connected.

The rotating base frame 30 has a hinge shaft 30c, a bar portion 30a, and a pair of attachment portions 30b provided to both ends of the bar portion 30a, each of which attachment portions 30b is in a flat plate-like shape. The hinge shaft 30c is connected to the shaft attachment portion 17 of the main body 11, with a torque (friction) exerted. As will be described later, each first arm 21 of the both parallel linking mechanisms 20 is coupled to the corresponding attachment portion 30b of the rotating base frame 30. In this case, the rotating base frame 30 functions as a “coupling member”.

The parallel linking mechanism 20 is provided with the first arm 21, a second arm 22, and a linking arm 23 which links them in a parallel manner.

As shown in FIG. 7, the first arm 21 has a shoulder portion 21a and an arm portion 21b provided extending from the shoulder portion 21a. The second arm 22 has a shape similar to that of the above-mentioned first arm 21, and has a shoulder portion 22a and an arm portion 22b. To the shoulder portion 21a of the first arm 21, as described above, the attachment portion 30b of the rotating base frame 30 is secured. This enables the first arm 21 to rotate integrally with the rotating base frame 30 around the hinge shaft 30c.

One end of the linking arm 23 is rotatably connected to the first arm 21 by a connecting shaft 25; and another end of the linking arm 23 is rotatably connected to the second arm 22 by a slide shaft 26.

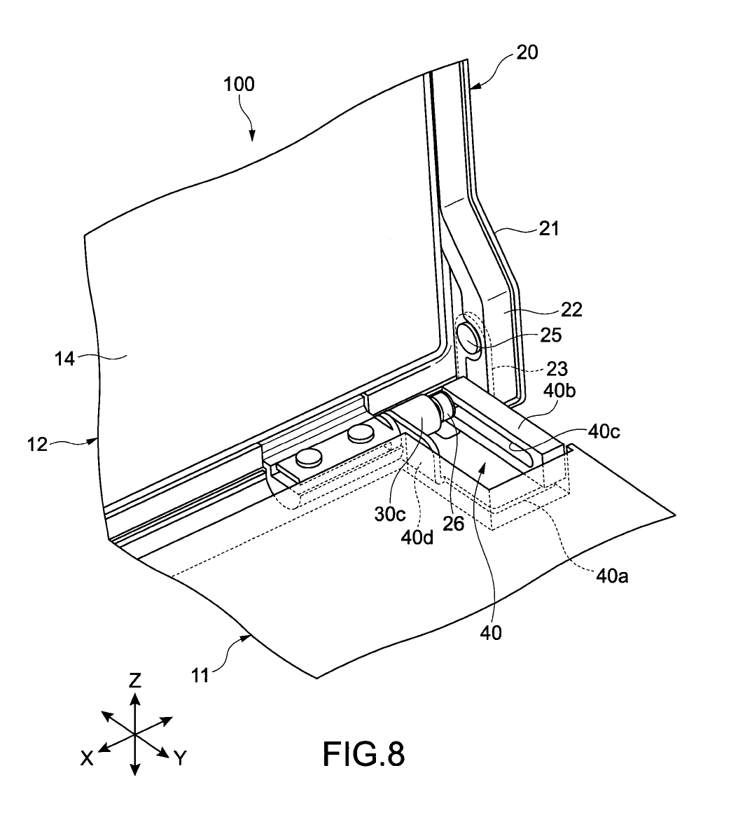

FIG. 8 is a perspective view showing a part near the shoulder portion 21a of each of the first and second arms 21 and 22 as seen from its inner side. In FIG. 8, illustration by drawing of the rotating base frame 30 is omitted. As shown in FIGS. 6 to 8, in order from the outside of the PC 100 inward, the shoulder portion 21a of the first arm 21, the shoulder portion 21a of the second arm 22, the linking arm 23 and the attachment portion 30b of the rotating base frame 30 are disposed.

A corner of the main body 11 is provided with a fixing base 40. The fixing base 40 is fixed to the main body 11. The fixing base 40 has a base plate 40a and a guide portion 40b formed in an outer side in the X-axis direction of the base plate 40a. The slide shaft 26 is slidably connected to the guide portion 40b. That is, the guide portion 40b guides sliding of the slide shaft 26. For example, the guide portion 40b may be provided with an elongate hole 40c formed along the Y-axis direction, and the slide shaft 26 may be slidably disposed in this elongate hole 40c.

On an inner part in the X-axis direction of the base plate 40a of the fixing base 40, a vertical plate 40d stands. To this vertical plate 40d, the above-mentioned hinge shaft 30c of the rotating base frame 30 is connected (see FIGS. 7 and 8).

As shown in FIGS. 6 and 7, the arm portions 21a and 21b of the first arm 21 and the second arm 21 are rotatably connected to the display body 12, by respective shaft portions at tip ends of these arm portions 21a and 21b. For example, to a side of the display body 12, a connecting member 24 to connect these arm portions 21a and 21b is attached. The connecting member 24 may be attached to the main body 11 in such a manner that the connecting member 24 has its length direction along a length direction of the side of the display body 12. That is, this makes the linking arm 23 and a display surface of the display body 12 parallel.

As shown in FIG. 4, the connecting member 24 is designed to have two shafts 27 and 28, provided with a distance a1 between the two shafts 27 and 28, the distance a1 being substantially the same as a distance a2 between the connecting shaft 25 and the slide shaft 26. That is, the first arm 21, the second arm 22, the linking arm 23 and the connecting member 24 forms a square shape of the parallel linking mechanism 20. For example, at the time when the square shape of the parallel linking mechanism 20 is a rectangular shape, each of the arm portions 21a and 21b of the first arm 21 and the second arm 22 forms an angle of 45 degrees with respect to the horizontal plane. At this time, the display surface of the display body 12 is perpendicular to the arm portions 21a and 21b; and the display surface also forms an angle of 45 degrees with respect to the horizontal plane.

At least regarding the first arm 21, its cross-section perpendicular to the longitudinal direction is formed roughly in an L shape. A cross-section of the second arm 22 perpendicular to the longitudinal direction is formed roughly in a U shape (or a shape of letter “ [symbol] ” in Katakana, Japanese) (see FIG. 8). A size of the second arm 22 in X direction seen from its cross-section is smaller than a size of the first arm 21 in X direction seen from its cross-section. Thus, as shown in FIGS. 4 and 5, in a state where the first arm 21, the second arm 22, the linking arm 23 and the connecting member 24 are parallel to one another, the second arm 22 would be arranged inside the first arm 21 on its outer side. It should be noted that alternatively the cross-section of the second arm 22 may have a similar L shape as that of the first arm 21.

By the four shafts being provided to the parallel linking mechanism 20 (slide shaft 26, connecting shaft 25, shaft portions 27 and 28), the parallel linking mechanism 20 is connected to each of the main body 11 and the display body 12 with a given torque (friction). Thus, in any one of the possible postures of the display portion 12 with respect to the main body 11, the PC 100 may keep the posture of the display portion 12 by the torque.

However, as will be described later, each of the four shafts of the parallel linking mechanism 20 does not always need to have such a torque that can keep any one of the postures of the display portion 12 with respect to the main body 11. Alternatively, as will be described later, the display portion 12 may be kept in the posture as shown in FIG. 6 by a mechanism such as a stopper.

In the shut state shown in FIG. 4, the slide shaft 26 is positioned at a rear slide end 40f (first slide end) which is a rear end of the elongate hole 40c of the guide portion 40b (see FIG. 10). The position of the slide shaft 26 positioned at the rear slide end 40f is coincident with the position of the hinge shaft 30c of the rotating base frame 30. When the slide shaft 26 is at the rear slide end 40f, the display body 12 would be in a state where the display body 12 is able to be opened and closed with respect to the main body 11, as in a normal notebook PC 100. Hereinafter, for convenience, this state will be referred to as a “clamshell state” and an opening and closing action of the display body 12 in such a state will be referred to as a “clamshell opening and closing action”.

On the other hand, in the tablet state as shown in FIG. 5, the slide shaft 26 is positioned at a front slide end 40e (second slide end) which is a front end of the elongate hole 40c of the guide portion 40b.

[Mechanical Actions of Information Terminal Apparatus]

Some mechanical actions of the PC 100 with the above configuration will now be described. The mechanical actions of this PC 100 include two types of opening and closing actions of: the above-mentioned “clamshell” opening and closing action and “tablet” opening and closing action.

(Clamshell Opening and Closing Action)

A state where the first arm 21, the second arm 22 and the linking arm 23 are parallel to one another and the slide shaft 26 is positioned at the rear slide end 40f of the guide portion 40b is the shut state (see FIGS. 2 and 4). From this state, the PC 100 is operable to make the above-mentioned clamshell opening and closing action.

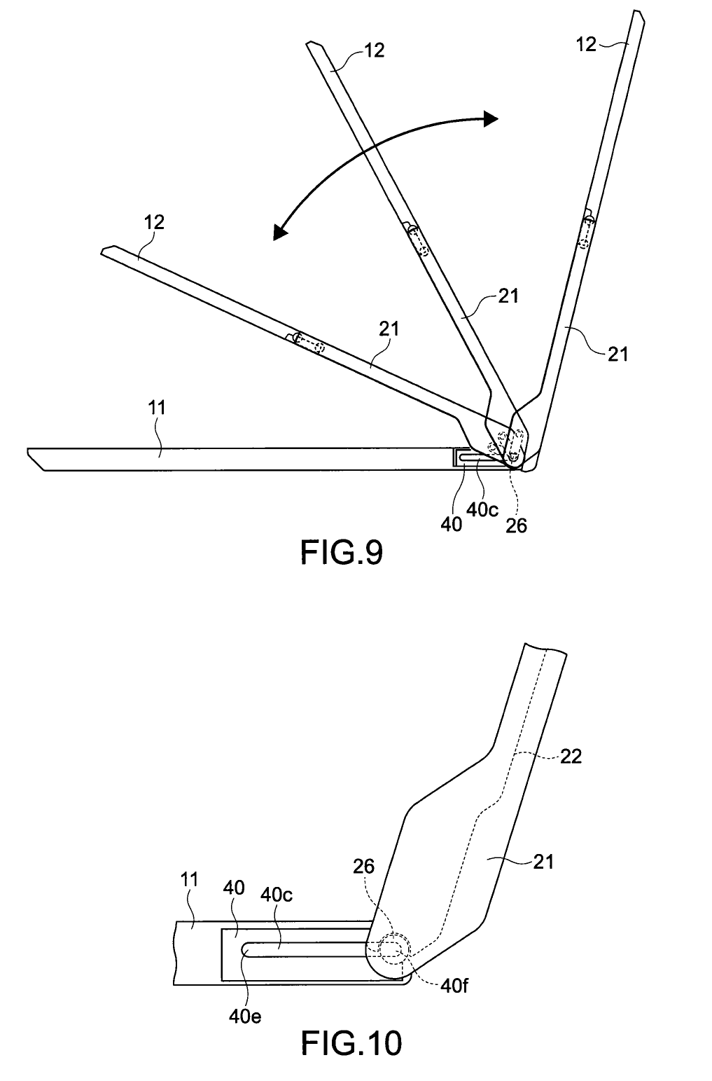

FIG. 9 is a figure showing the clamshell opening and closing action. Referring also to FIG. 10, in a state where the first arm 21, the second arm 22 and the linking arm 23 are kept parallel and the slide shaft 26 coincides with the hinge shaft 30c; the display body 12, the parallel linking mechanism 20 and the rotating base frame 30 moves integrally. That is, in the clamshell opening and closing action, by rotation of the display body 12 and the parallel linking mechanism 20 around the hinge shaft 30c of the rotating base frame 30, the display body 12 opens and closes with respect to the main body 11.

(Tablet Opening and Closing Action)

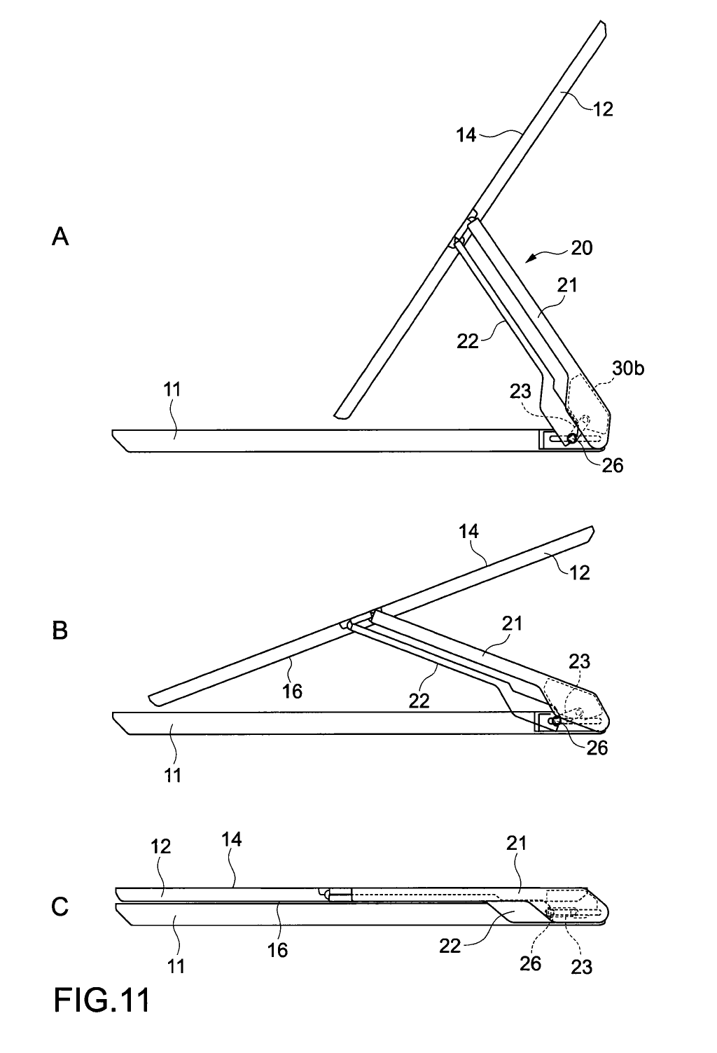

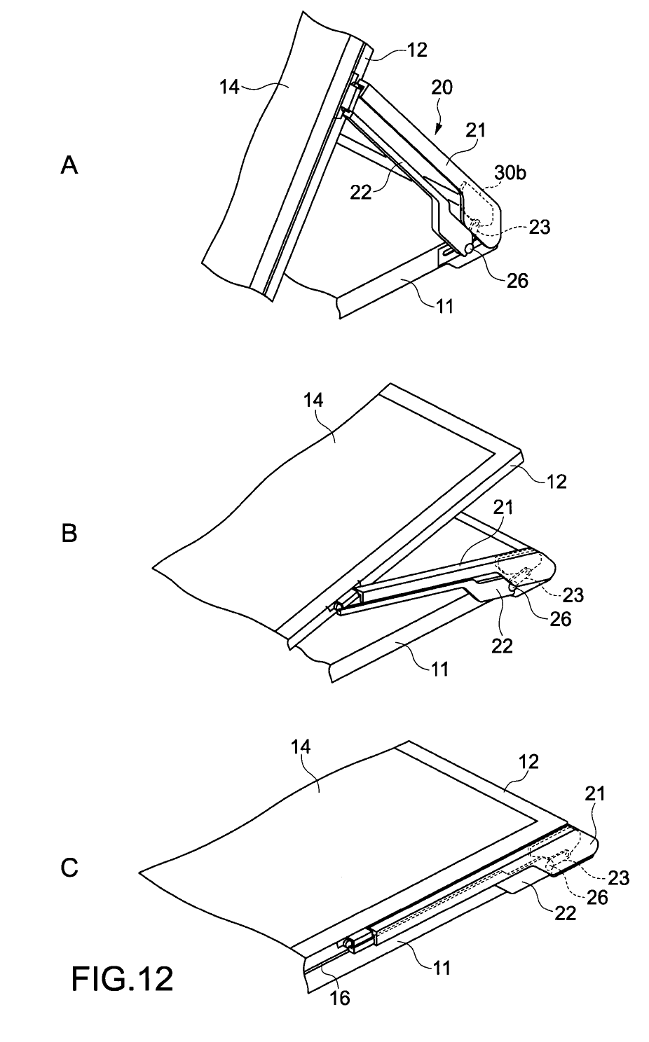

FIGS. 11A to 11C are figures showing the tablet opening and closing action. The tablet opening and closing action is an action in which the display 12 moves with respect to the main body 11 by the operation of the parallel linking mechanism 20. FIGS. 12A to 12C are figures showing the actions of the parallel linking mechanism 20 each corresponding to the action timings of FIGS. 11A to 11C. FIG. 13 is a perspective view showing the PC 100 being in the state shown in FIG. 11A.

For example, as shown in FIG. 1, from a state where the display body 12 stands up along the Z-axis direction (state of 90 degrees), the user can start the operation of the tablet opening and closing action. In addition, the user can operate the parallel linking mechanism 20 in such a manner that the PC, from the tablet state shown in FIG. 11C, can be in the state where the display body 12 stands up along the Z-axis direction.

The state shown in FIG. 1 is a state where the slide shaft 26 coincides with the hinge shaft 30c, as described above. From the state shown in FIG. 1, by the operation of the parallel linking mechanism 20, as the slide shaft 26 moves toward the front slide end 40e from the guide portion 40b, the display body 12 rotates in such a manner that the display surface of the display portion 14 of the display body 12 is turned away from the main body 11, that is, turned upward. The action of the PC 100 at that time is shown in order, in FIGS. 11A to 11C and FIGS. 12A to 12C. The state shown in FIGS. 11B and 12B corresponds to the state shown in FIG. 7.

The state of the PC 100 shown in FIGS. 11C and 12C is the same as the state shown in FIG. 5. In this state, the main body 11 and the display body 12 may overlap in such a manner that a surface (opposite surface) 16 of the display body 12, which surface 16 is provided on a side opposite to the surface provided with the display portion 14, can face the main body 11. In other words, this is a state where the display surface faces upward, and it allows the user to use the PC 100 as a tablet PC.

As described above, the PC 100 according to this embodiment can at least have the clamshell state as shown in FIG. 9 and the tablet state as shown in FIG. 3. Further, since the main body 11 and the display body 12 are connected by the parallel linking mechanism 20, the display body 12 is able to move with respect to the main body 11 in accordance with the movement of the parallel linking member 20. That is, as the posture of the display body 12 can be set in accordance with the angle of the arms 21 and 22 of the parallel linking member 20, the posture of the display body 12 can be stabilized.

In contrast, the above-mentioned device described in Patent Document 1 may not be able to have a stable posture since the second casing may rotate through an angle of more than 360 degrees.

In the parallel linking member 20 according to this embodiment, the slide shaft 26 of the linking arm 23 is operable to slide along the guide portion 40b. This allows the operation of the parallel linking member 20 while keeping the posture of the display body 12 stable with respect to the main body 11.

The pair of right and left parallel linking mechanisms 20 is secured to the rotating base frame 30, and is configured to move integrally with the rotating base frame 30. This facilitates synchronization in movement of the pair of right and left parallel linking mechanisms 20; and enhances the rigidity thereof (rigidity of both of their first arms 21). As a result, the movement of the display body 12 can be more stable.

In this embodiment, the rotating base frame 30 having the function of coupling both of the parallel linking mechanisms 20 is made to have the hinge shaft 30c. This may make it unnecessary to provide a separate rotating shaft if the coupling member is provided; and allow enhancement of the rigidity of both of the first arms 21 of the parallel linking mechanisms 20 while allowing downsizing of the PC 100.

In the above embodiment, the torque (friction) of the four shafts of the parallel linking mechanism 20 (slide shaft 26, connecting shaft 25, shaft portions 27 and 28) does not always need to be such a torque that can keep any one of the postures of the display portion 12 with respect to the main body 11. That is, in this case, in the middle of the movement of the display portion 12 made by the user, the PC 100 may not keep the posture thereof (the postures shown in FIGS. 6 and 13) with only the torque of the four shafts. In such a case, when the PC100 is in any posture of the tablet opening and closing action, in addition to the above-mentioned torque of the four shafts 25 to 28, the PC 100 may be provided with a restriction member, which is not shown, to restrict the movement of the display portion 12 and the main body 11.

An example of this restriction member is a member (or a mechanism) made of a material such as rubber which has high friction coefficient, the member being provided on at least one of: a bottom end of the display body 12; and a confronting surface 11a (the surface that confronts the display body 12, that is, an upper surface) (see FIG. 13) of the main body 11. In cases where the restriction member is to be provided on the confronting surface of the main body 11, the restriction member may be disposed in a region other than the regions in which the keyboard 13 and the touch pad 15 are disposed. Examples of implementation of the member having high friction coefficient may include processing a part or the whole of the main body 11 to increase its friction coefficient.

Alternatively, as the restriction member, it is also possible to provide a mechanical or magnetic stopper on at least one of the bottom end of the display body 12 and the confronting surface of the main body 11.

Examples of the mechanic stopper include a protrusion, a recess, a notch, a slider mechanism and the like. The slider mechanism is, for example, a mechanism for shifting, among a plurality of stages having different angles of the display body 12.

Examples of implementation of the magnetic stopper include the following. For example, in order that the display body 12 would be able to keep its posture in the position such as those shown in FIGS. 6 and 13, a permanent magnet may be disposed on a given position in the display body 12 (or the main body 11) and a ferromagnetic substance may be disposed on a given position in the main body 11 (or the display body 12).

[Form of Software Applied to Information Terminal Apparatus]

The PC 100 as the information terminal apparatus may basically have the following four possible states.

(1) Shut state (see FIG. 2)

(2) Clamshell state (see FIGS. 1 and 9)

(3) Tablet state (see FIG. 3)

(4) Viewer state (a halfway state of the tablet opening and closing action) (for example, see FIGS. 11A and 13)

The viewer state is a state which may be taken mainly for the purpose of allowing the user to watch (view) the display portion 14 of the display body 12 rather than allowing an operation input to the PC 100. The viewer state may be taken when the user watches the movies, TV broadcasts and other images (including moving and still images) which are displayed on the display portion 14.

The viewer state may be, for example, as shown in FIG. 13, a state where the display body 12 hides the keyboard 13 but does not hide the touch pad 15 as viewed in the Z-axis direction. However, the viewer state may also be defined as any state where the posture of the display body 12 is in a given angle with respect to the main body 11, an angle set by the user's choice, or the like.

Of course, as will be described later, the PC 100 may be configured to receive operation input from the user through at least the touch pad 15 or the like, even during its viewer state as well.

The PC 100 may detect which state the PC 100 is in among the above (2) to (4); and may activate or switch software in accordance with the detected state of the PC 100. Or, it may detect which of the above state (2) and (3) the PC 100 is in; and may activate or switch the software in accordance with the detected state of the PC 100. Or, it may detect which of the above state (3) and (4) the PC 100 is in; and may activate or switch the software in accordance with the detected state of the PC 100.

As used herein, “switch” is a concept that includes “activate”. The meaning of the term “switch” includes, in addition to this “activate”, processing by a CPU for making a software program executable by allowing inactive software, which was already started, to be active.

The software may be an OS (Operating System), or may be application software that operates in an OS. For example, it is possible to activate a first OS when the PC 100 is in the clamshell state; and to activate a second OS which is different from the first OS, when the state of the PC is changed by the user to the tablet state. That is, it may be dual-boot. Of course, it is not limited to such an example. The PC may also be operable to switch three or more OS in accordance with the corresponding state of the PC. The following may be mentioned as an example: one in which the first OS is Windows (registered trademark), the second OS is Android (registered trademark), and a third OS is iOS.

Or, the PC 100 may switch different user interfaces (UI) within one OS in accordance with the corresponding state of the PC 100. For example, in cases where the OS is “Windows (registered trademark) 8”, a normal UI may be used when the PC 100 is in the clamshell state; and Metro UI may be used when the PC 100 is in the tablet state.

Alternatively, the software to be switched is not limited to OS, and such software to be switched may be applications.

For example, it is possible that in cases where the state of the PC 100 is switched to the viewer state from the clamshell state or the tablet state, the PC may automatically start an application for reproducing videos.

Alternatively, there is an application that enables setting of assignment of operation input with respect to the whole or a part of a screen of the display portion 14 when it is in the viewer state. Such an application allows an operation screen for touch-operation input by the display portion 14 to be displayed, in the entire area or a partial area of the display portion 14, when it is in the viewer state. The operation screen is, for example, an operation screen related to reproduction of videos. The operation screen would be segmented to a plurality of (for example, three or more) areas, and these areas for operation may be: right-side area for fast forward; middle area for play and stop; left-side area for fast backward, and the like.

As another example of the application, the PC 100 may be provided with an application for switching to enable and disable the touch-operation input to the display portion 14 in accordance with the state of the PC 100. For example, the PC 100 may enable the touch-operation input when the PC 100 is in the tablet state; and disable the touch-operation input in the other states of the PC 100. This allows the user to make an input by touch operation to the display portion 14 only at the time while the PC 100 is in the tablet state.

Otherwise, it is not limited to the touch operation to the display portion 14, and the PC 100 may perform switching to enable and disable the operation input of the keyboard 13, or the touch pad 15, or the like, in accordance with the state of the PC 100.

Here, a detecting mechanism which detects the different states of the PC 100 mentioned above may include, for example, one which uses magnetic or electrical detection. In cases where the detecting mechanism uses magnetic detection, a magnetic sensor or a permanent magnet may be disposed on each of the first arm 21 and the second arm 22 of the parallel linking mechanism 20. In cases where the detecting mechanism uses electrical detection, one of the members that make up the parallel linking mechanism 20 and another one of the members may be provided with an electrical conduction part therebetween.

For example, as a mechanism for detecting the viewer state and the other states, a permanent magnet may be disposed in the main body 11 (or the bottom end of the display body 12) while a magnetic sensor is disposed in the bottom end of the display body 12 (or the main body 11).

### Other Embodiments

The present disclosure is not limited to the above embodiment, and various other embodiments can be implemented.

In addition to that the display body 12 has the display portion 14; the main body may have another display portion as well. In this case, the main body may or may not be provided with the keyboard 13 as hardware. On the confronting surface (upper surface) of the main body 11, one of the keyboard and the touch pad may be omitted.

Alternatively, the PC 100 may have a main body configured in such a fashion that the keyboard of the PC 100 is on the front side of the main body and the touch pad is on the rear side.

The information terminal apparatus may have a function of a mobile phone, and the like. In this case, the size of the information terminal apparatus may be modified as appropriate.

It is also possible to have a parallel linking mechanism in which a shaft connecting the linking arm 23 and the second arm 22 (corresponding to the slide shaft 26 in the above embodiment) is not connected to the main body 11; so that the parallel linking mechanism is configured to be moved freely in the Z-Y plane.

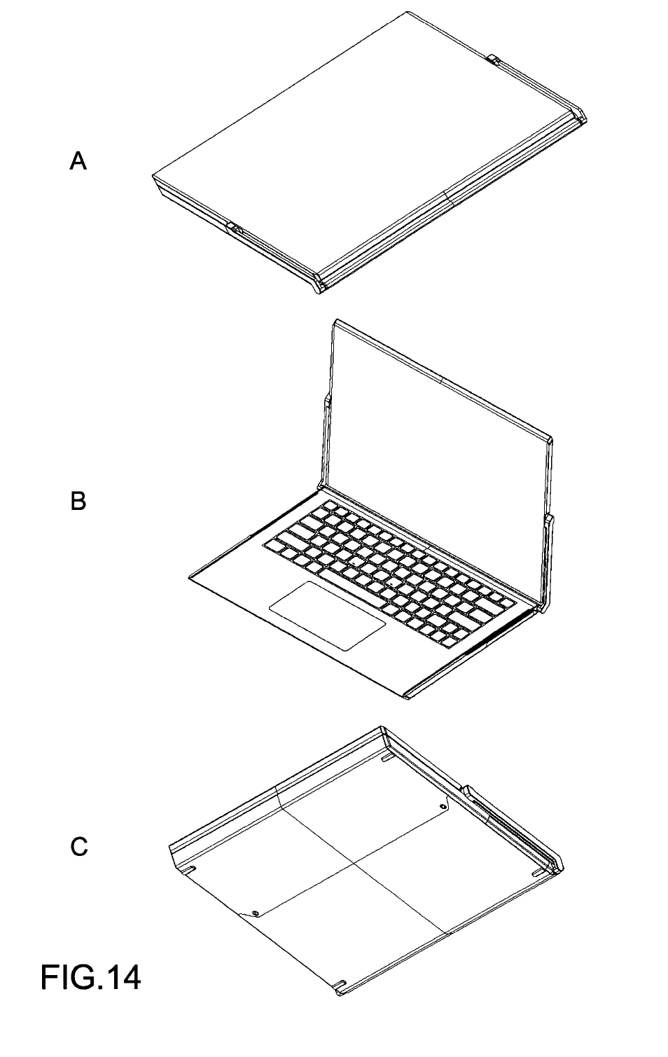

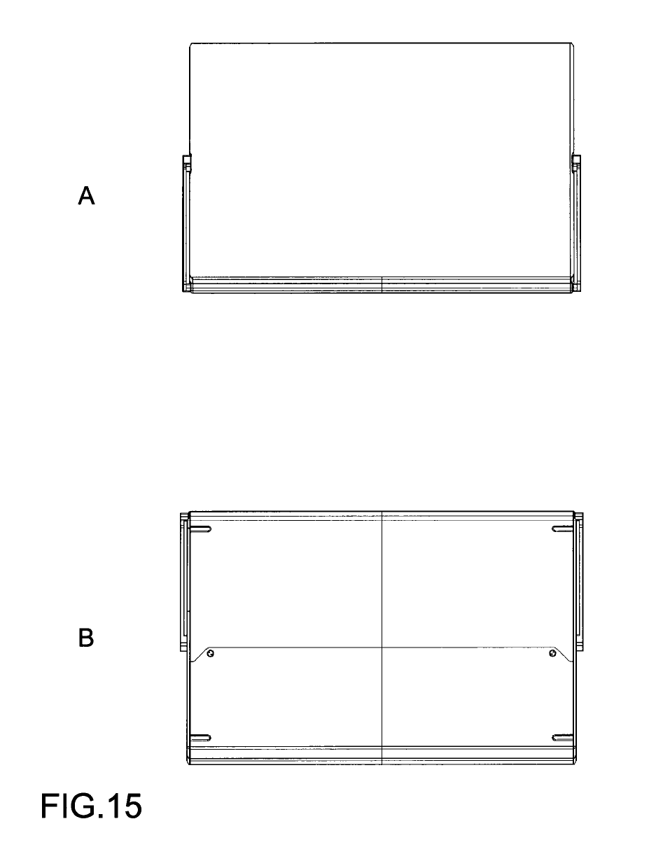

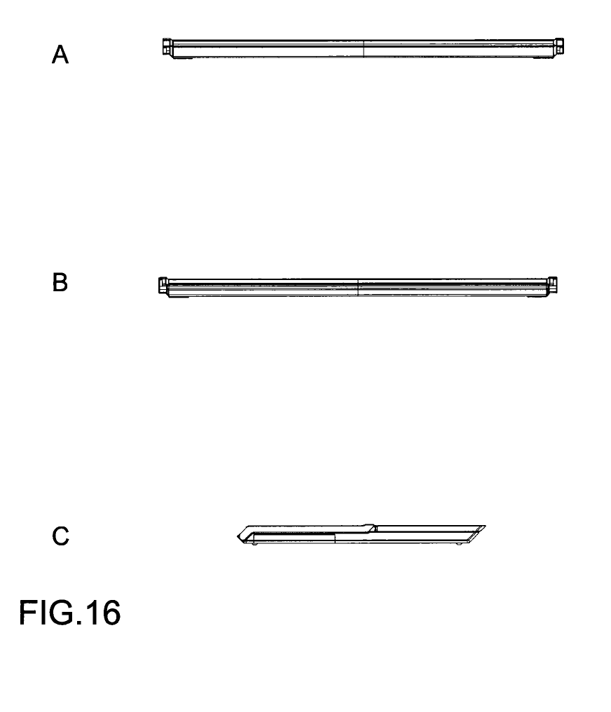

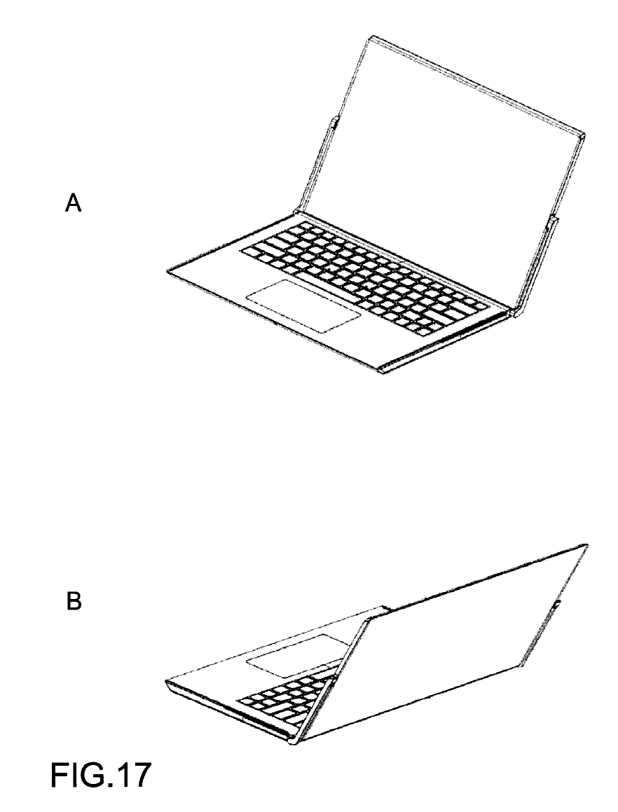

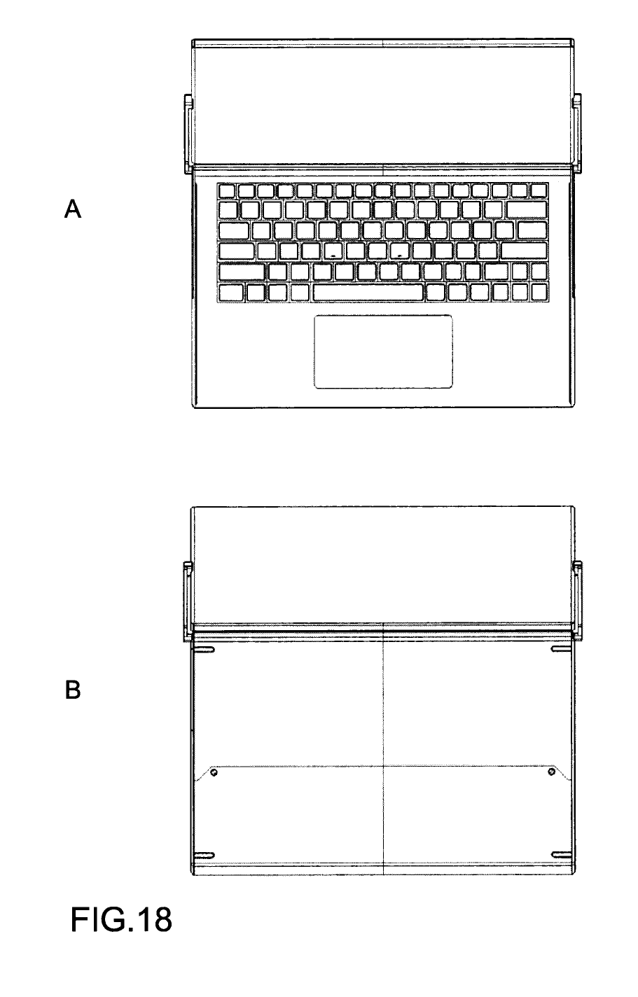

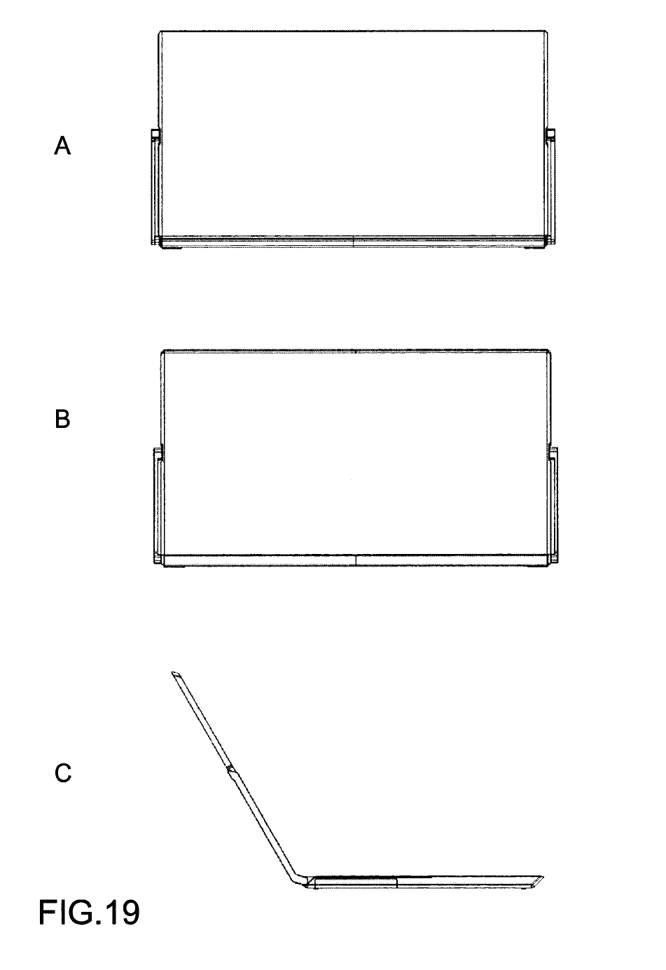

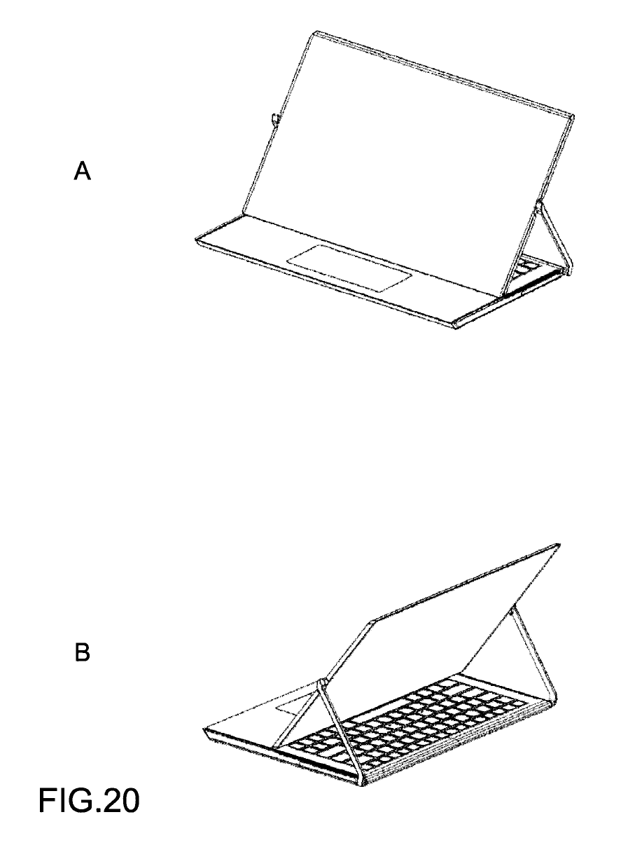

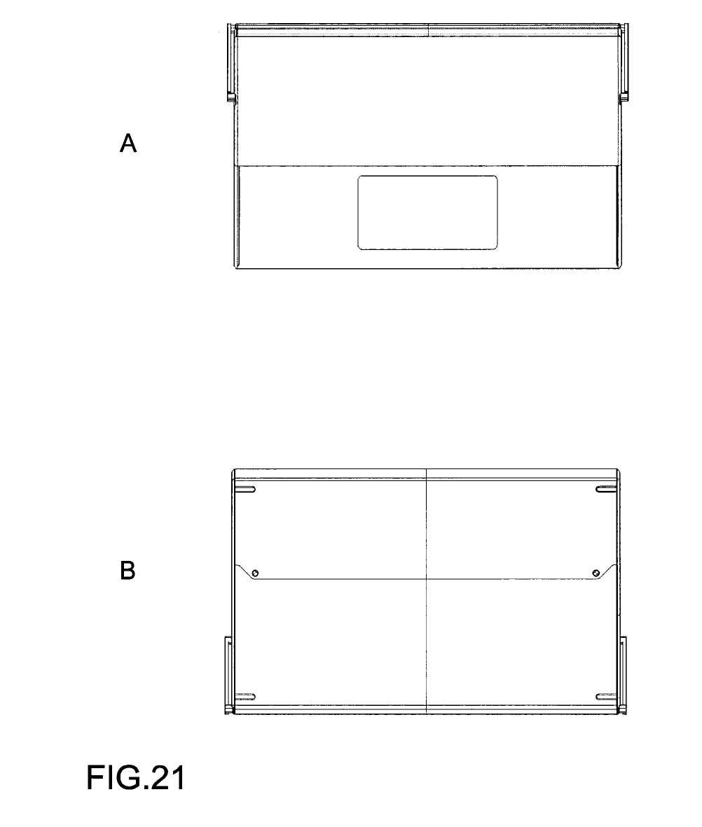

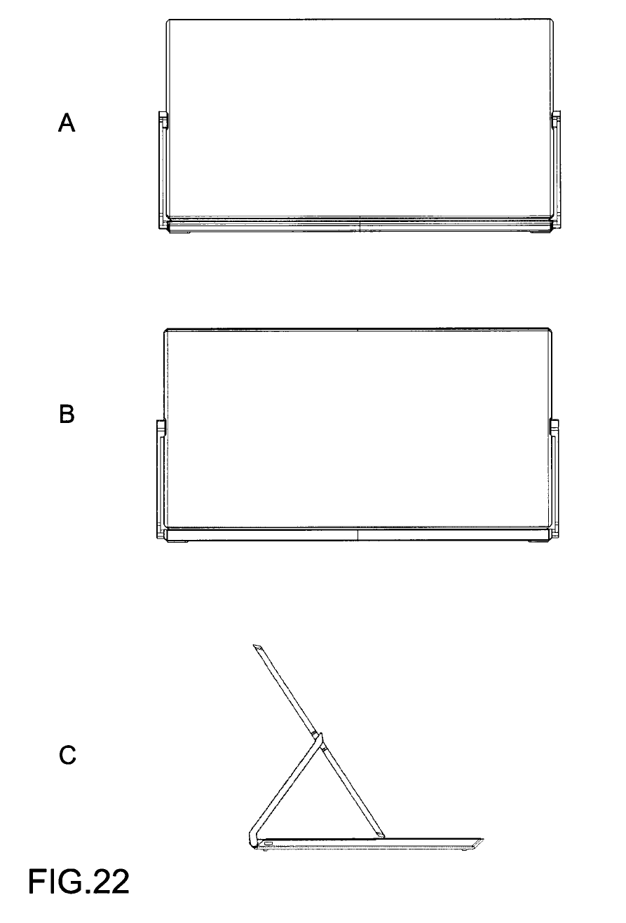

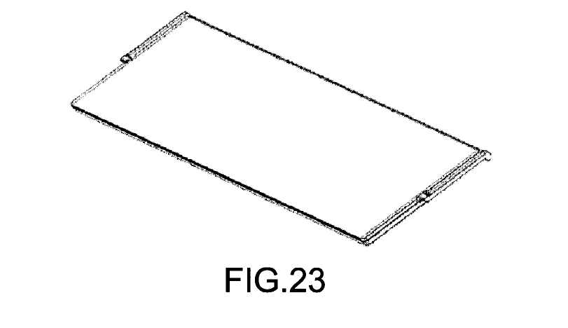

FIGS. 14 to 23 show some information terminal apparatuses (computers) according to more other embodiments, in which, parallel linking mechanisms are used.

Out of the characteristic parts of the embodiments described above, at least two characteristic parts can be combined.

The present disclosure may employ the following configurations.

(1) An information terminal apparatus including:

a first body;

a second body;

a rotating shaft connected to the first body; and

a parallel linking mechanism capable of rotating in an integrated manner with the rotating shaft, the parallel linking mechanism having
a first arm rotatably connected to the second body,
a second arm rotatably connected to the second body, and
a linking arm to link the first arm to the second arm in a parallel manner.

(2) The information terminal apparatus according to (1), further including

a display portion having a display surface being provided in parallel to the linking arm, the display portion being provided on the second body.

(3) The information terminal apparatus according to (2), in which

the parallel linking mechanism has a slide shaft which is connected, rotatably and slidably with respect to the first body, to a part where the second arm and the linking arm are connected.

(4) The information terminal apparatus according to (3), in which

the first body has a guide portion including
a first slide end and
a second slide end opposite to the first slide end,

which guide portion guides sliding of the slide shaft.

(5) The information terminal apparatus according to (4), in which

the slide shaft is configured to coincide with the rotating shaft in a state where the slide shaft is positioned at the first slide end of the guide portion.

(6) The information terminal apparatus according to (4), in which

the second body is rotatable integrally with the first arm, the second arm and the linking arm, around the rotating shaft, in a state where the slide shaft is coincident with the rotating shaft.

(7) The information terminal apparatus according to (5) or (6), in which

the display portion is provided on the second body,

the second body has
a display surface provided in parallel to the linking arm, the display surface being provided on the display portion, and
an opposite surface provided on a side of the second body opposite to the display surface; and

in which

the first body and the second body overlap in such a manner that the first arm, the second arm and the linking arm are in parallel, and the opposite surface of the second body faces the first body, in a state where the slide shaft is positioned at the second slide end of the guide portion.

(8) The information terminal apparatus according to any one of (1) to (7), in which

the parallel linking mechanism is provided in a mechanism having a pair of parallel linking mechanisms disposed in both sides of the first body.

(9) The information terminal apparatus according to (8), further including

a coupling member to couple first arms of the pair of parallel linking mechanisms integrally to each other.

(10) The information terminal apparatus according to (9), in which

the coupling member has the rotating shaft.

### DESCRIPTION OF REFERENCE SYMBOLS

11 main body
12 display body
14 storage element
20 parallel linking mechanism
21 first arm
22 second arm
23 linking arm
26 slide shaft
30 rotating base frame
30c hinge shaft
40 fixing base
40b guide portion
40e front slide end
40f rear slide end
100 PC (information terminal apparatus)

1. An information terminal apparatus comprising:
a first body;
a second body;
a rotating shaft connected to the first body; and
a parallel linking member capable of rotating in an integrated manner with the rotating shaft, the parallel linking member having
a first arm rotatably connected to the second body,
a second arm rotatably connected to the second body, and
a linking arm to link the first arm to the second arm in a parallel manner.

2. The information terminal apparatus according to claim 1, further including
a display portion having a display surface being provided in parallel to the linking arm, the display portion being provided on the second body.

3. The information terminal apparatus according to claim 2, wherein
the parallel linking member has a slide shaft which is connected, rotatably and slidably with respect to the first body, to a part where the second arm and the linking arm are connected.

4. The information terminal apparatus according to claim 3, wherein
the first body has a guide portion including
a first slide end and
a second slide end opposite to the first slide end,
which guide portion guides sliding of the slide shaft.

5. The information terminal apparatus according to claim 4, wherein
the slide shaft is configured to coincide with the rotating shaft in a state where the slide shaft is positioned at the first slide end of the guide portion.

6. The information terminal apparatus according to claim 4, wherein
the second body is rotatable integrally with the first arm, the second arm and the linking arm, around the rotating shaft, in a state where the slide shaft is coincident with the rotating shaft.

7. The information terminal apparatus according to claim 5, wherein
the display portion is provided on the second body,
the second body has
a display surface provided in parallel to the linking arm, the display surface being provided on the display portion, and
an opposite surface provided on a side of the second body opposite to the display surface; and
wherein
the first body and the second body overlap in such a manner that the first arm, the second arm and the linking arm are in parallel, and the opposite surface of the second body faces the first body, in a state where the slide shaft is positioned at the second slide end of the guide portion.

8. The information terminal apparatus according to claim 1, wherein
the parallel linking member is provided in a mechanism having a pair of parallel linking members disposed in both sides of the first body.

9. The information terminal apparatus according to claim 8, further including
a coupling member to couple first arms of the pair of parallel linking members integrally to each other.

10. The information terminal apparatus according to claim 9, wherein
the coupling member has the rotating shaft.
